(19) United States
(12) Patent Application Publication
(10) Pub. No.: US 2002/0139552 A1
(43) Pub. Date: Oct. 3, 2002

(54) Extraction structure of metallic antimagnetic cover

(75) Inventor: Chi-Yao Chang, Kuishan Hsiang (TW)

Correspondence Address: BRUCE H. TROXELL, SUITE 1404, 5205 LEESBURG PIKE, FALLS CHURCH, VA, 22041, US

(73) Assignee: SPEED TECH CORP.

(21) Appl. No.: 10/102,820

(22) Filed: Mar. 22, 2002

(30) Foreign Application Priority Data
Mar. 27, 2001 (TW) 90204652

(51) Int. Cl. H05K 9/00

(52) U.S. Cl. 174/35 R

(57) ABSTRACT

Extraction structure of metallic antimagnetic cover. The antimagnetic cover is formed by punching to have an upper cover and a shield body. Multiple bridge sections are formed between the upper cover and the shield body to connect the upper cover with the shield body. A vacuum sucker is used to suck the upper cover to overlay the antimagnetic cover on the chip. Then a hand tool is thrust into the extraction hole of the upper cover for extracting the upper cover from the shield body. Accordingly, the upper side of the chip is open, while the periphery of the chip is shielded by the shield body to isolate the chip from electromagnetic wave.

### BACKGROUND OF THE INVENTION

The present invention is related to an extraction structure of metallic antimagnetic cover. The antimagnetic cover is formed by punching to have an upper cover and a shield body connected by bridge sections. The upper cover provides increased area for a vacuum sucker to suck the antimagnetic cover. After the antimagnetic cover is overlaid on the chip, a hand tool is thrust into the extraction hole of the upper cover to extract the upper cover from the shield body. The antimagnetic cover can be easily assembled and manufactured at low cost.

The existent mobile phones, PDA, etc. have light weight, thin thickness and small volume. Correspondingly, the chips used in these products are thinner and thinner. In order to prevent electromagnetic wave from interfering with the chip during operation, an antimagnetic cover is used to cover the chip for isolating the chip from electromagnetic wave. In addition, in order not to increase the thickness and occupied space, the periphery of the chip is shielded, while the upper side of the chip is open. After assembled, the upper surface of the chip is attached to the casing. Casings of mobile phones and PDA made of aluminum-magnetism alloy have been developed. Such material not only enhances heat-radiation efficiency, but also is able to isolate the chip from electromagnetic wave. Therefore, the effect of isolation from electromagnetic wave is focused on the periphery of the chip. Referring to FIGS. 7 and 8, the conventional antimagnetic cover has an upper cover A and a frame body B. The edges of the upper cover A have multiple downward extending lugs A1. The inner face of each lug A1 is formed with an engaging protuberance A11. The edges B1 of the frame body B are formed with corresponding engaging holes B11. When the upper cover A is mated with the frame body B, the lugs A1 hold the edges B1 of the frame body B with the engaging protuberance A11 engaged in the engaging holes B11 to locate the upper cover A. The upper cover A is formed with multiple extraction holes A2. After the antimagnetic cover covers the chip C, a hand tool D is thrust into the extraction hole A2 to extract the upper cover A from the frame body B. Accordingly, the upper side of the chip C is open, while the periphery of the chip is shielded and isolated from the electromagnetic wave. When assembled, the fine component is sucked by a vacuum sucker. The upper cover is formed with extraction holes which are too dense to provide sufficient area for the vacuum sucker to suck the upper cover. Therefore, the upper cover must be manually assembled. Moreover, the upper cover and frame body are two pieces which must be made by two molds. Furthermore, in order to connect the upper cover with the frame body, the upper cover and frame body must be additionally processed. This wastes time and increases manufacturing cost. Also, the electromagnetic wave affects the periphery of the chip. The engaging holes formed on the edges of the frame body will decrease the isolation effect for electromagnetic wave.

### SUMMARY OF THE INVENTION

It is therefore a primary object of the present invention to provide an extraction structure of metallic antimagnetic cover. The antimagnetic cover is formed by punching to have an upper cover and a shield body. Multiple bridge sections are formed between the upper cover and the shield body to connect the upper cover with the shield body. The upper cover provides increased area for a vacuum sucker to suck the antimagnetic cover. After the antimagnetic cover is overlaid and located on the chip, a hand tool is thrust into the extraction hole of the upper cover to forcedly break the bridge sections and thus extract the upper cover from the shield body. Accordingly, the upper side of the chip is open, while the periphery of the chip is shielded by the shield body to isolate the chip from electromagnetic wave. Accordingly, the antimagnetic cover can be easily assembled and manufactured at low cost.

The present invention can be best understood through the following description and accompanying drawings wherein;

### BRIEF DESCRIPTION OF THE DRAWINGS

FIG. 1 is a perspective view of the present invention;

FIG. 2 is a sectional view showing that the chip is not yet covered by the present invention;

FIG. 3 is a sectional view showing that the chip is covered by the present invention;

FIG. 4 is a sectional view showing that the upper cover of the present invention is not yet extracted;

FIG. 5 is a sectional view showing that the upper cover of the present invention is being extracted;

FIG. 6 is a sectional view showing that the upper cover of the present invention is extracted;

FIG. 7 is a perspective exploded view of a conventional antimagnetic cover; and

FIG. 8 is a sectional view showing that the upper cover of the conventional antimagnetic cover is being extracted.

### DETAILED DESCRIPTION OF THE PREFERRED EMBODIMENTS

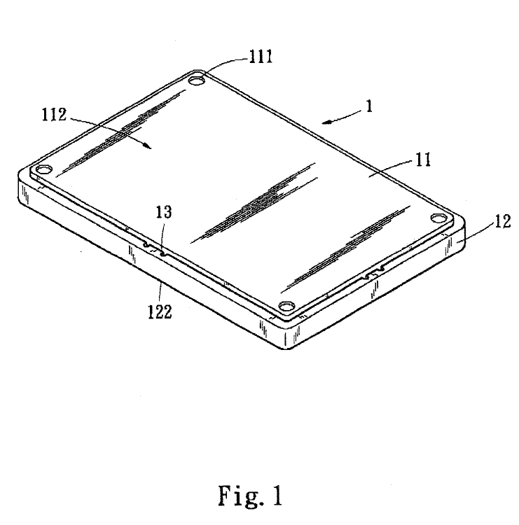

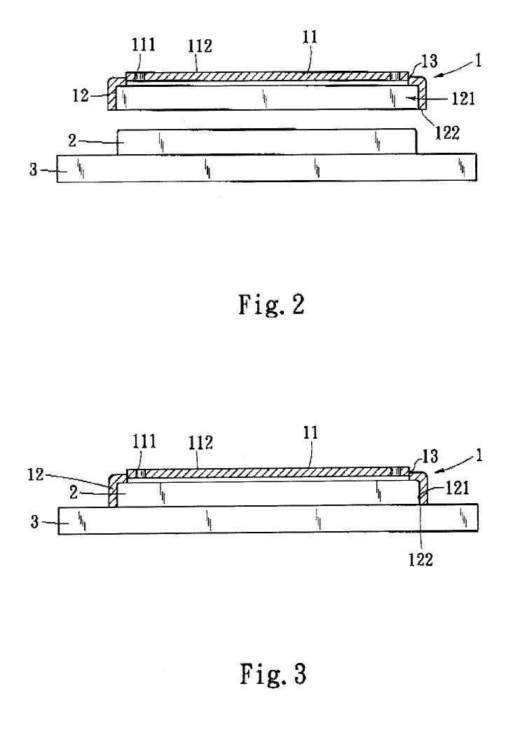

Please refer to FIGS. 1 and 2. The metallic antimagnetic cover 1 is made by punching, whereby the central portion of the top face of the antimagnetic cover 1 is disaligned from the peripheral side board thereof. Accordingly, the antimagnetic cover 1 is formed to have an upper cover 11 and a shield body 12. The punched portion between the upper cover 11 and the shield body 12 is formed with multiple bridge sections 13. Each corner of the upper cover 11 is formed with an extraction hole 111. The center of the upper cover 11 is formed with a plane face 112.

Referring to FIGS. 2 and 3, the interior of the shield body 12 of the antimagnetic cover 1 is formed with a hollow receptacle 121. When moving the antimagnetic cover I to cover the chip 2, a vacuum sucker is used to suck the plane face 112 of the upper cover 11 to accommodate the chip 2 in the receptacle 121 of the antimagnetic cover 1. The bottom 122 of the shield body 12 abuts against the surface of the circuit board 3 and is fixedly integrally connected therewith. Furthermore, after the antimagnetic cover 1 covers the chip 2, the shield body 12 embraces the chip 2 to shield the top face and lateral sides of the chip 2.

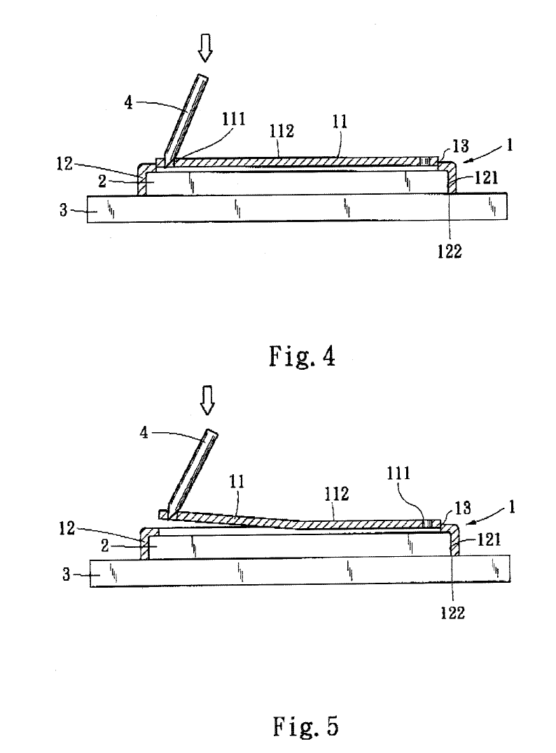

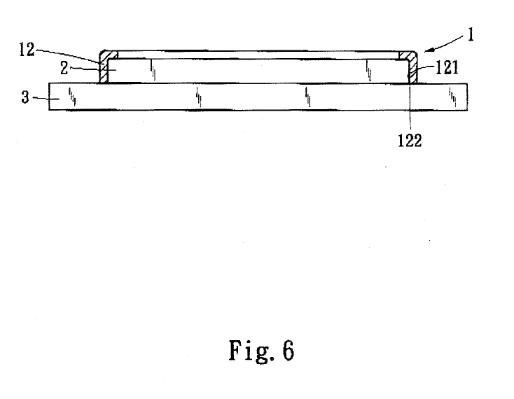

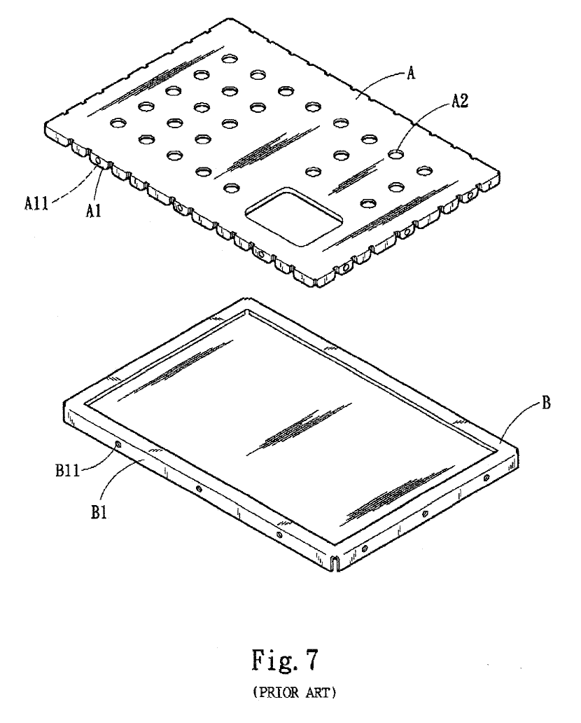

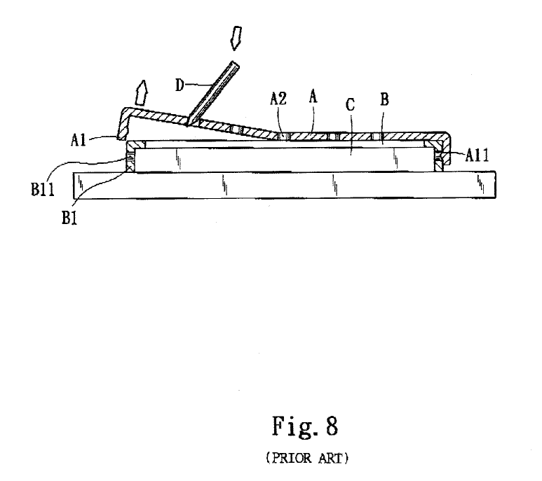

Referring to FIGS. 4, 5 and 6, after the antimagnetic cover 1 covers the chip 2, a hand tool 4 is used to thrust into the extraction hole 111 of the upper cover 11. Then a lateral force is exerted onto the hand tool 4 to bend and deform the upper cover 11 and forcedly break the bridge sections 131 between the upper cover 11 and the shield body 12. At this time, the upper cover 11 is disconnected front the shield body 12 and the upper side of the chip 2 is open, while the periphery of the chip 2 is shielded to effectively isolating the chip 2 from electromagnetic wave.

In addition, by means of adjusting the punching force exerted onto the bridge sections 131 between the upper cover 11 and the shield body 12, the disalignment height of the upper cover 11 from the shield body 12 can be changed. In the case that the bottom face of the upper cover 11 is higher than the top face of the shield body 12, it is unnecessary to additionally punch the upper cover 11 to form the extraction holes 111. Instead, the hand tool 4 can be directly thrust into the gap between the upper cover 11 and the shield body 12 for extracting the upper cover 11 from the shield body 12.

The above embodiments are only used to illustrate the present invention, not intended to limit the scope thereof. Many modifications of the above embodiments can be made without departing from the spirit of the present invention.

What is claimed is:

1. Extraction structure of metallic antimagnetic cover, by means of punching, a central portion of the antimagnetic cover being disaligned from a periphery thereof to form an upper cover and a shield body, the punched portion between the upper cover and the shield body being formed with multiple bridge sections connecting the upper cover with the shield body without separation, when a hand tool is used to exert a force onto the upper cover, the bridge sections are easily breakable to extract the upper cover from the shield body.

2. Extraction structure of metallic antimagnetic cover as claimed in claim 1, wherein each corner of the upper cover is formed with an extraction hole for the hand tool to thrust therein, the center of the upper cover being formed with a plane face.

3. Extraction structure of metallic antimagnetic cover as claimed in claim 1, wherein the bottom face of the upper cover is higher than the top face of the shield body, whereby a gap is formed between the upper cover and the shield body and the hand tool can be thrust into the gap to extract the upper cover from the shield body.
